(19) United States
(12) Patent Application Publication
(10) Pub. No.: US 2006/0205170 A1
(43) Pub. Date: Sep. 14, 2006

(54) Methods of forming self-healing metal-insulator-metal (MIM) structures and related devices

(76) Inventor: Glenn A. Rinne, Apex, NC (US)

Correspondence Address: MYERS BIGEL SIBLEY & SAJOVEC, PO BOX 37428, RALEIGH, NC, 27627, US

(21) Appl. No.: 11/365,768

(22) Filed: Mar. 1, 2006

Related U.S. Application Data
(60) Provisional application No. 60/659,789, filed on Mar. 9, 2005.

(51) Int. Cl. H01L 21/20

(52) U.S. Cl. 438/381

(57) ABSTRACT

Methods of forming metal-insulator-metal structures may include providing a first conductive electrode on a substrate, forming a dielectric layer on the first conductive electrode, and forming a second conductive electrode on the dielectric layer so that the dielectric layer is between the first and second conductive electrodes. In addition, a conductive layer may be formed between the dielectric layer and one of the first and second conductive electrodes wherein the conductive layer includes a conductive material that decomposes into a non-conductive material once a threshold temperature has been exceeded. Related structures are also discussed.

### RELATED APPLICATION

The present application claims the benefit of priority from U.S. Provisional Application No. 60/659,789 filed Mar. 9, 2005, the disclosure of which is hereby incorporated herein in its entirety by reference.

### FIELD OF THE INVENTION

The present invention relates to the field of electronics, and more particularly, to methods of forming metal-insulator-metal structures and related devices.

### BACKGROUND

Electronic devices such as integrated circuits employing field effect transistors (also referred to as MOS integrated circuits) and/or discrete devices (such as light emitting diodes) may be susceptible to electrostatic discharge. Given the decreasing size of circuit features resulting from improving process technologies, static electricity generated by normal activity can destroy or substantially harm many electronic devices. Electronic devices such as integrated circuit and/or discrete devices may be most susceptible to damage as packaged devices which have not yet been assembled into a finished product.

U.S. Pat. No. 5,276,350 discusses a zener diode with a low reverse breakdown avalanche voltage for electrostatic discharge (ESD) protection in integrated circuit devices. U.S. Patent No. U.S. Pat. No. 5,914,501 discusses a light emitting diode assembly incorporating a power shunting element that prevents damage to the LED from electrostatic discharge. The disclosures of U.S. Pat. Nos. 5,276,350 and 5,914,501 are hereby incorporated herein in their entirety by reference.

### SUMMARY

According to embodiments of the present invention, methods of forming metal-insulator-metal structures may include providing a first conductive electrode on a substrate, forming a dielectric layer on the first conductive electrode, and forming a second conductive electrode on the dielectric layer so that the dielectric layer is between the first and second conductive electrodes. In addition, a conductive layer may be formed between the dielectric layer and one of the first and second conductive electrodes with the conductive layer comprising a conductive material that decomposes into a non-conductive material once a threshold temperature has been exceeded.

More particularly, the conductive layer may be formed after forming the dielectric layer and before forming the second conductive electrode. The first conductive electrode may include a metal layer, and forming the dielectric layer may include converting a surface portion of the metal layer into an oxide. The metal layer may include at least one of aluminum and/or tantalum, and the dielectric layer may include at least one of aluminum oxide and/or tantalum oxide. Moreover, the second conductive layer may be formed using thin film deposition on the conductive layer.

The conductive material may include a conductive metal oxide that decomposes into a non-conductive metal oxide once the threshold temperature has been exceeded. More particularly, the conductive layer may include manganese dioxide (MnO₂), and the conductive manganese dioxide (MnO₂) may decompose into insulating manganic oxide (Mn₂O₃) once the threshold temperature has been exceeded. The dielectric layer may include an insulating metal oxide such as aluminum oxide and/or tantalum oxide, and each of the first and second conductive electrodes may include a metal such as aluminum and/or tantalum.

The substrate may be an integrated circuit substrate including an input/output pad, and one of the first or second conductive electrodes may be coupled to the input/output pad. Moreover, one of the first or second conductive electrodes may be directly coupled to the input/output pad through a conductive runner on the substrate.

In an alternative, the first electrode may be coupled to a first terminal of an electronic device such as a discrete electronic device, and the second electrode may be coupled to a second terminal of the electronic device. For example, the first electrode may be coupled to a first terminal of a light emitting diode (LED), and the second electrode may be coupled to a second terminal of the light emitting diode. More particularly, the first electrode may be coupled to the first terminal using at least one of a solder bond and/or a wirebond.

The substrate may be rigid and at least a portion of each of the dielectric layer, the second conductive electrode, and the conductive layer may be parallel with respect to a surface of the substrate. According to particular embodiments, the first conductive electrode may include tantalum and the second conductive electrode may include a tantalum sub-layer and an aluminum sub-layer such that the tantalum sub-layer is between the aluminum sub-layer and the first conductive electrode. Moreover, providing the first conductive electrode may include forming the first conductive electrode using thin film deposition on the substrate.

According to additional embodiments of the present invention, metal-insulator-metal structures may include a substrate, a first conductive electrode on the substrate, a dielectric layer on the first conductive electrode, and a second conductive electrode on the dielectric layer so that the dielectric layer is between the first and second conductive electrodes. In addition, a conductive layer may be provided between the dielectric layer and one of the first and second conductive electrodes wherein the conductive layer comprises a conductive material that decomposes into a non-conductive material once a threshold temperature has been exceeded.

The conductive material may include a conductive metal oxide that decomposes into a non-conductive metal oxide upon exceeding the threshold temperature. More particularly, the conductive layer may include manganese dioxide (MnO₂) wherein the conductive manganese dioxide (MnO₂) decomposes into insulating manganic oxide (Mn₂O₃) upon exceeding the threshold temperature. The dielectric layer may include an insulating metal oxide such as aluminum oxide and/or tantalum oxide, and each of the first and second conductive electrodes may include a metal such as aluminum and/or tantalum.

The substrate may include an integrated circuit substrate having an input/output pad, and one of the first or second conductive electrodes may be coupled to the input/output pad. More particularly, one of the first or second conductive electrodes may be directly coupled to the input/output pad through a conductive runner on the substrate.

In an alternative, an electronic device (such as a discrete electronic device) may have a first terminal coupled to the first electrode and a second terminal coupled to the second terminal. For example, the electronic device may be a light emitting diode. Moreover, the first terminal may be coupled to the first electrode using at least one of a solder bond and/or a wirebond.

The substrate may be rigid and at least a portion of each of the dielectric layer, the second conductive electrode, and the conductive layer may be parallel with respect to a surface of the substrate. According to particular embodiments of the present invention, the first conductive electrode may include tantalum and the second conductive electrode may include a tantalum sub-layer and an aluminum sub-layer such that the tantalum sub-layer is between the aluminum sub-layer and the first conductive electrode. Moreover, the first conductive electrode and the surface of the substrate may include different materials, and the conductive layer may be between the dielectric layer and the second conductive electrode.

### BRIEF DESCRIPTION OF THE DRAWINGS

FIGS. 1A-C are cross-sectional views illustrating steps of forming MIM structures on integrated circuit devices according to embodiments of the present invention.

FIGS. 2A-D are cross-sectional views illustrating steps of forming MIM structures on sub-mounts for electronic devices according to embodiments of the present invention.

FIGS. 3 and 4 are cross-sectional views illustrating sub-mounts for electronic devices according to embodiments of the present invention.

### DETAILED DESCRIPTION

The present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art.

In the drawings, the thickness of layers and regions are exaggerated for clarity. It will also be understood that when an element such as a layer, region or substrate is referred to as being on another element, it can be directly on the other element or intervening elements may also be present. In contrast, if an element such as a layer, region or substrate is referred to as being directly on another element, then no other intervening elements are present. Similarly, when an element such as a layer, region or substrate is referred to as being coupled or connected to/with another element, it can be directly coupled or connected to/with the other element or intervening elements may also be present. In contrast, if an element such as a layer, region or substrate is referred to as being directly coupled or connected to/with another element, then no other intervening elements are present. As used herein, the term “and/or” includes any and all combinations of one or more of the associated listed items. The symbol “/” is also used as a shorthand notation for “and/or”.

Furthermore, relative terms, such as beneath, upper, lower, top, and/or bottom may be used herein to describe one element's relationship to another element as illustrated in the figures. It will be understood that relative terms are intended to encompass different orientations of the device in addition to the orientation depicted in the figures. For example, if the device in one of the figures is turned over, elements described as below other elements would then be oriented above the other elements. The exemplary term below, can therefore, encompasses both an orientation of above and below.

It will be understood that although the terms first and second are used herein to describe various regions, layers and/or sections, these regions, layers and/or sections should not be limited by these terms. These terms are only used to distinguish one region, layer or section from another region, layer or section. Thus, a first region, layer or section discussed below could be termed a second region, layer or section, and similarly, a second region, layer or section could be termed a first region, layer or section without departing from the teachings of the present invention. Like numbers refer to like elements throughout.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

According to embodiments of the present invention, thin film metal-insulator-metal (MIM) structures may be used to provide electrostatic discharge (ESD) protection for microelectronic devices. More particularly, an MIM structure for ESD protection may include a first metal electrode on a surface of a substrate, a dielectric layer on the first metal electrode, and a conductive layer on the dielectric layer wherein the conductive layer comprises a material (such as manganese dioxide MnO₂) that decomposes into a non-conductive material (such as manganic oxide Mn₂O₃) once a temperature threshold has been exceeded. In addition, the MIM structure may include a second metal layer on the conductive layer so that the dielectric layer is between the first metal electrode and the conductive layer, and so that the conductive layer is between the dielectric layer and the second metal electrode.

MIM structures according to embodiments of the present invention may provide protection for an electronic device from electrostatic discharge (ESD) by permitting current tunneling through the dielectric layer when an ESD threshold voltage for the electronic device is exceeded. Moreover, the MIM structure may be self-healing in the event of dielectric breakdown because portions of the conductive layer in the vicinity of a dielectric breakdown may be converted to a non-conductive material due to a localized temperature rise in the vicinity of the dielectric breakdown. Accordingly, a short-circuit and/or excessive leakage current may be cured even though dielectric breakdown has occurred in one or more locations on the dielectric layer. At normal operating voltages of the electronic device, the dielectric layer (together with any portions of the conductive layer that may have been converted to a non-conductive material) may substantially block current flow.

More particularly, each of the first and second metal electrodes may include aluminum and/or tantalum, and the conductive layer may comprise a metal oxide such as manganese dioxide (MnO₂). Moreover, the dielectric layer may be formed by oxidation, anodization, and or electrolytic reaction of an exposed portion of the first metal layer to provide a uniform, thin, and/or high-quality dielectric layer. By providing a sufficiently thin dielectric layer using oxidation, anodization, and/or electrolytic reaction, the MIM structure may provide rectifying characteristics. Such an MIM structure may thus be referred to as an MIM diode. According to particular embodiments, the first metal electrode may be a layer of tantalum, the dielectric layer may be a layer of tantalum oxide, the conductive layer may be a layer of manganese dioxide, and the second conductive electrode may include sub-layers of tantalum and aluminum (with the tantalum sub-layer between the aluminum sub-layer and the conductive layer).

An MIM structure according to embodiments of the present invention can thus be formed on an integrated circuit substrate with one electrode of the MIM structure being coupled to an input/output pad and the other electrode being coupled to a ground of the integrated circuit substrate. Energy from an electrostatic discharge (ESD) can thus be coupled through the MIM structure thereby protecting circuitry of the integrated circuit device. An MIM structure according to other embodiments of the present invention may be formed on a substrate of a sub-mount for a discrete electronic device (such as a light emitting diode LED) or integrated circuit device, and the MIM structure may be coupled in parallel with the discrete electronic device to provide ESD protection therefore.

On an integrated circuit substrate, the first metal layer may be deposited, for example, using a thin film deposition technique such as sputtering, chemical vapor deposition (CVD), atomic layer deposition (ALD), etc., and the dielectric layer may be formed as an oxide of the first metal layer using oxidation, anodization, and/or electrolytic reaction of a surface portion of the first metal layer. After forming the dielectric layer, a conductive layer of manganese dioxide (MnO₂) may be deposited, for example, by sputtering and/or application in an aqueous solution and drying. After forming the conductive layer of manganese dioxide, the second metal electrode may be deposited, for example, using a thin film deposition technique, such as sputtering, chemical vapor deposition (CVD), atomic layer deposition (ALD), etc., on the conductive layer of manganese dioxide. As used herein, the term deposition refers to the formation of a layer/film on an existing layer/film as opposed to the placement of a preformed layer such as a foil.

On a sub-mount, the first metal electrode may be deposited, for example, using a thin film deposition technique, such as sputtering, chemical vapor deposition (CVD), atomic layer deposition (ALD), etc., on a surface of an insulating or conducting substrate of the sub-mount. In an alternative, a substrate of the sub-mount may be metal, and a surface portion of the metal sub-mount provide the first metal electrode. The dielectric layer may be formed as an oxide of the first metal layer using oxidation, anodization, and/or electrolytic reaction of a surface portion of the first metal electrode. After forming the dielectric layer, the conductive layer of manganese dioxide (MnO₂) may be deposited, for example, by sputtering and/or by application in an aqueous solution and drying. After forming the conductive layer of manganese dioxide, the second metal electrode may be deposited, for example, using a thin film deposition technique, such as sputtering, chemical vapor deposition (CVD), atomic layer deposition (ALD), etc., on the conductive layer of manganese dioxide. As used herein, the term deposition refers to the formation of a layer/film on an existing layer/film as opposed to the placement of a preformed layer such as a foil.

Thin film MIM structures according to embodiments of the present invention may provide non-linear, semiconductor properties due to differences in work functions at interfaces between layers (e.g. between the first metal electrode and the dielectric layer). More particularly, MIM structures according to embodiments of the present invention may allow electron tunneling through the dielectric layer at relatively high voltages providing a diode curve characteristic. During an electrostatic discharge event, energy from the discharge may be coupled through the MIM structure (with current tunneling through the dielectric layer) to protect a microelectronic device(s) coupled to the MIM structure.

The dielectric layer, however, may breakdown due to voltage overstress during an electrostatic discharge event thereby generating a pinhole through the dielectric layer, and metal from the first metal electrode may migrate across the pinhole in the dielectric layer. In the event of dielectric breakdown, sufficient heat may be generated at the point of dielectric breakdown so that portions of the conductive layer (e.g. manganese dioxide MnO₂) in the vicinity of the dielectric breakdown decompose into an insulating material (e.g. manganic oxide Mn₂O₃) so that a short circuit between the first and second metal electrodes does not result. More particularly, manganese dioxide may decompose into manganic oxide and oxygen at temperatures above about 500 degrees C. according to the formula provided blow:
500 degrees C.2×MnO₂→Mn₂O₃+O.
Portions of the conductive manganese dioxide in the vicinity of the dielectric breakdown may thus decompose into insulating manganic oxide (Mn₂O₃) so that a short circuit is self-healing. Moreover, oxygen generated during the decomposition may react with metal from the first metal electrode exposed through the dielectric layer to convert the exposed metal to an insulating oxide further insulating the site of dielectric breakdown.

While the decomposition temperature of a conductive material such as manganese dioxide (MnO₂) may be above expected processing and/or operating temperatures for an integrated circuit device and/or electronic assembly including an MIM structure according to embodiments of the present invention, a dielectric breakdown occurring during an ESD event may generate much higher localized temperatures. Accordingly, only a small portion of a conductive layer of manganese dioxide (MnO₂) in the immediate vicinity of a dielectric breakdown may be converted into insulating manganic oxide (Mn₂O₃) during an electrostatic discharge (ESD) event, so that the MIM structure may continue to provide ESD protection without a short circuit or excessive leakage current after one or more breakdowns in the dielectric layer.

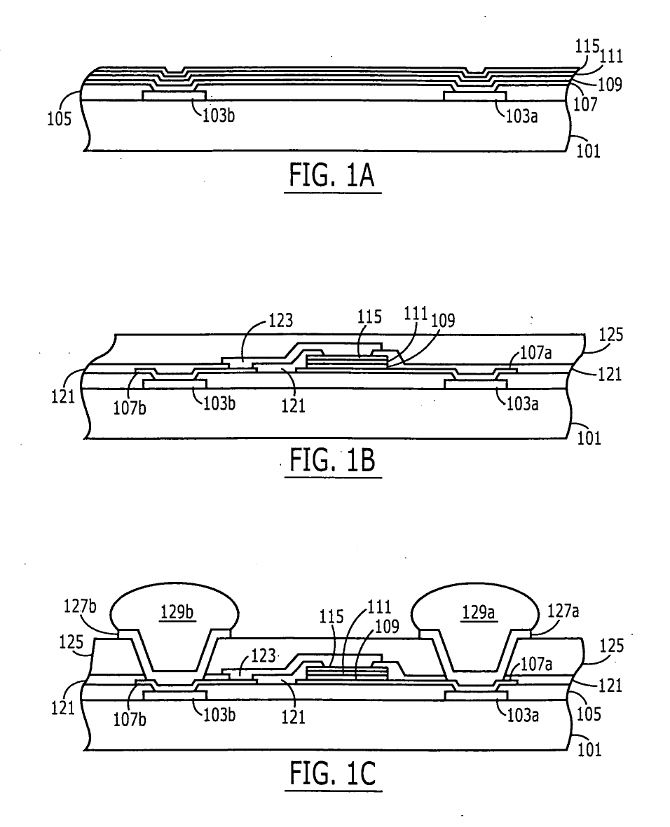

According to particular embodiments of the present invention illustrated in FIGS. 1A-C, an MIM structure may provide electrostatic discharge protection on an integrated circuit device. More particularly, an integrated circuit substrate 101 may include a semiconductor material and a plurality of electronic circuits (such as transistors, diodes, resistors, capacitors, and/or inductors) therein. Moreover, pads (such as metal pads) 103a-b may provide electrical coupling with electronic circuits of the substrate 101. The pad 103a, for example, may be an input/output pad, and the pad 103b may be a reference voltage (such as ground or power supply) pad. Each of the pads may thus provide a point of electrical coupling with a next level of packaging (such as a printed circuit board, a sub-mount, a leadframe, another integrated circuit device, an electronic module, etc.). An insulating layer 105 may provide protection for the integrated circuit substrate 101 and contact holes in the insulating layer 105 may expose portions of the pads 103a-b. While two pads 103a-b are illustrated in FIG. 1A by way of example, it will be understood that any number of pads may be provided on an integrated circuit device.

As further shown in FIG. 1A, a first metal layer 107, a dielectric layer 109, a conductive layer 111 (that decomposes into a non-conductive material once a temperature threshold has been exceeded), and a second metal layer 115 may be sequentially formed on the insulating layer 105 and on exposed portions of the pads 103a-b. The first and second metal layers 107 and 115, for example, may include aluminum and/or tantalum and may be formed using a thin film deposition technique, such as sputtering, chemical vapor deposition (CVD), atomic layer deposition (ALD), etc. The dielectric layer 109 may be an oxide of the metal of the first metal layer 107 (e.g. tantalum oxide and/or aluminum oxide), and the dielectric layer 109 may be formed by reacting oxygen with the exposed surface of the first metal layer 107, for example, using oxidation, anodization, and/or electrolytic reaction. The conductive layer 111 may be a layer of a conductive metal oxide (such as manganese dioxide MnO₂) that decomposes into an insulating metal oxide (such as manganic oxide Mn₂O₃) once a threshold temperature is exceeded. A conductive layer 111 of manganese oxide may be deposited, for example, by sputtering and/or by application in an aqueous solution and drying.

As shown in FIG. 1B, the dielectric layer 109, the conductive layer 111, and the second metal layer 115 may be patterned using a single patterning mask to provide an MIM structure according to embodiments of the present invention. After patterning the dielectric layer 109, the conductive layer 111, and the second metal layer 115 (also referred to as a second metal electrode), the first metal layer 107 may be patterned to provide a first metal layer 107a (also referred to as a first metal electrode) coupled to the first pad 103a and a second metal layer 107b coupled to the second pad 103b. The first metal layer 107a may provide a circular pad portion adjacent the first pad 103a, an electrode portion adjacent the patterned dielectric layer 109, and a runner portion electrically coupling the circular pad and electrode portions. The second metal layer 107b may provide a circular pad portion adjacent the second pad 103b and a runner portion for subsequent coupling to the second metal layer 115 of the MIM structure. While pad portions of the metal layers 107a and 107b are illustrated as being adjacent the respective pads 103a and 103b, pad portions of one or both of the metal layers 107a and 107b may be redistributed from respective pads 103a and 103b with runner portions of the metal layers providing coupling between the redistributed pad portions of the metal layers 107a and 107b and the pads 103a and 103b. Accordingly, subsequently formed solder bumps may be provide adjacent respective integrated circuit pads 103a and 103b or redistributed therefrom.

An insulating layer 121 may be formed on the MIM structure (including the patterned dielectric layer 109, the patterned conductive layer 111, and the second metal layer 115), on the metal layer 107 (including portions 107a and 107b), and on the insulating layer 105. In addition, the insulating layer 121 may be patterned to expose portions of the runner of the metal layer 107b and to expose portions of the patterned metal layer 115 of the MIM structure. A conductive layer 123 (such as a layer of a metal) can then be formed on the insulating layer 121, on exposed portions of the metal layer 107b, and on exposed portions of the metal layer 115, and the conductive layer 123 can be patterned to provide an electrical coupling between the metal layer 115 and the metal layer 107b. An insulating layer 125 may then be formed on the metal layer 115 and the insulating layer 121.

The insulating layers 121 and 125 may then be patterned to expose portions of circular pads of metal layers 107a and 107b, as shown in FIG. 1C. Underbump metallurgy layers 127a and 127b may be provided on exposed portions of respective metal layers 107a and 107b, and solder bumps 129a and 129b may be provided on the respective underbump metallurgy layers 127a and 127b. The solder bumps 129a and 129b may be formed, for example, by electroplating. More particularly, some portion of the underbump metallurgy layers may initially provide a continuous electroplating conduction layer across the insulating layer 125, a plating template (such as a photoresist mask) may expose portions of the electroplating conduction layer for electroplating solder, and then, the plating template and portions of the electroplating conduction layer not covered by solder may be removed after electroplating. Underbump metallurgy layers and electroplating of solder are discussed, for example, in U.S. Pat. No. 6,117,299, U.S. Pat. No. 5,162,257, U.S. Pat. No. 5,293,006, U.S. Pat. No. 5,767,010, U.S. Pat. No. 6,222,279, U.S. Pat. No. 5,902,686, and U.S. Pat. No. 5,381,946. Each of these patents are assigned to the assignee of the present invention, and the disclosures of these patents are hereby incorporated herein in their entirety by reference.

In an alternative, preformed solder balls may be placed on the underbump metallurgy layers 127a and 127b either before or after patterning the underbump metallurgy layers. In another alternative, wire bonding pads may be provided in addition to or instead of the underbump metallurgy layers, and wire bonds may be provided instead of solder bumps. Solder bumps, wire bonds, and/or any other interconnection technologies known to those having skill in the art can be used to provide electrical and/or mechanical connection between the pads 103a and 103b and a next level of packaging such as a printed circuit board, a sub-mount, a leadframe, another integrated circuit device, an electronic module, etc.

As shown in FIG. 1C, the MIM structure includes portions of metal layer 107a, dielectric layer 109, conductive layer 111, and metal layer 115, and the MIM structure is electrically connected between the metal pads 103a and 103b. During normal operation of the integrated circuit device at normal operating voltages, the MIM structure substantially blocks electrical communication between the pads 103a and 103b. If an excessive voltage is generated between the pads 103a and 103b (for example, as a result of an electrostatic discharge), electron tunneling through the dielectric layer 109 of the MIM structure may allow current flow to dissipate energy thereby protecting circuitry of the integrated circuit substrate 101.

Moreover, the conductive layer 111 may provide self-healing for the MIM structure in the event of breakdown of the dielectric layer 109. In particular, the conductive layer 111 may comprise a conductive material (such as manganese dioxide) that decomposes into an insulating material (such as manganic oxide) once a temperature threshold is exceeded. Accordingly, a dielectric breakdown resulting from an electrostatic discharge may provide a localized increase in temperature of the conductive layer 111 in the vicinity of the dielectric breakdown above the threshold for decomposition, so that portions of the conductive layer in the vicinity of the breakdown decompose into an insulating material. A short circuit and/or excessive leakage current between the pads 103a and 103b may thus be avoided even though dielectric breakdown of the dielectric layer 109 has occurred. Moreover, the MIM structure may provide ESD protection after one or more breakdowns of the dielectric layer because the conductive layer 111 maintains its conductivity away from the region(s) of prior dielectric breakdown(s).

While a single MIM structure is illustrated in FIG. 1C, two or more MIM structures may be coupled in series or parallel between the pads 103a and 103b. For example, a second MIM structure may be formed on an extended portion of the metal layer 107b, with the conductive layer 123 providing an electrical connection between the second metal layers of the two MIM structures. Stated in other words, a second MIM structure may be provided between the conductive layer 123 and the metal layer 107b. Such a structure may provide a symmetry of response regardless of whether an electrical bias between the pads 103a and 103b is positive or negative. In such a structure, both MIM structures may be formed simultaneously using the same deposition and patterning steps.

In another alternative, a second MIM structure may be cross-coupled in parallel with the first MIM structure between the pads 103a and 103b. For example, a first MIM structure (including a self-healing conductive layer such as layer of manganese dioxide) may be formed on a portions of the metal layer 107a, and a second MIM structure (including a self-healing conductive layer such as a layer of manganese dioxide) may be formed on portions of the metal layer 107b. Then, a top electrode of the first MIM structure can be coupled to a portion of the second metal layer 107b, and a top electrode of the second MIM structure can be coupled to a portion of the first metal layer 107a. One or the other of the MIM structures may thus provide a primary current path depending on a polarity of a voltage applied across the two pads 103a and 103b during an electrostatic discharge event.

According to additional embodiments of the present invention, the conductive layer 123 may provide a second metal electrode for the MIM structure so that a separate metal layer 115 is not required. Moreover, a first metal electrode for the MIM structure may be provided in addition to the metal layer 107a so the first metal electrode of the MIM structure and the metal layer 107a may comprise different materials. For example, a first metal electrode of aluminum and/or tantalum may be provided between the dielectric layer 109 and the metal layer 107a, and the metal layer 107a may include a layer of a metal such as copper, chromium, titanium, etc. More particularly, the metal layer 107a may include an adhesion layer (such as a layer of titanium and/or chromium) adjacent the insulating layer 121, and a conduction layer (such as a layer of copper) on the adhesion layer.

Each of the underbump metallurgy layers 127a and 127b may include an adhesion layer (such as a layer of chromium, titanium, tungsten, and/or combinations thereof) adjacent the insulating layer 125, a conduction layer (such as a layer of copper) on the adhesion layer, and a conductive barrier and/or passivation layer (such as a layer of nickel, platinum, palladium, gold and/or combinations thereof) on the conduction layer. Moreover, the underbump metallurgy layers may provide redistribution of one or both of the solder bumps from the respective pads 103a and 103b on the insulating layer 125. Redistribution of solder bumps is discussed, for example, in U.S. Pat. No. 6,329,608, U.S. Pat. No. 5,892,179, and U.S. Pat. No. 6,378,691. Each of these patents is assigned to the assignee of the present invention, and the disclosures of these patents are hereby incorporated herein in its entirety by reference. One or more of an adhesion layer, a conduction layer, and/or a barrier and/or passivation layer may be provide as a continuous layer on the insulating layer 125 and then portions thereof removed after forming solder bumps. In addition or in an alternative, barrier and/or passivation layers may be selectively plated before plating the solder bumps.

The solder bumps 129a and 129b may be bumps of one or more different solder materials. For example, the solder bumps may include one or more of a single element and/or a binary, ternary, and/or higher order solder; such as a lead-tin solder, a lead-bismuth solder, a lead-indium solder, a lead free solder, a tin-silver solder, a tin-silver-copper solder, an indium-tin solder, an indium-gallium solder, a gallium solder, an indium-bismuth solder, a tin-bismuth solder, an indium-cadmium solder, a bismuth-cadmium solder, a tin-cadmium solder, etc. Accordingly, the underbump metallurgy layers 127a and 127b may provide surfaces that are wettable to the solder bumps wherein the solder wettable surface of the underbump metallurgy layers 127a and 127b and the solder bumps 129a and 129b comprise different materials.

As shown in FIG. 1C, surface portions of the substrate 101 and/or the insulating layer 105 may be planar, and portions of the metal layer 107a, the dielectric layer 109, the conductive layer 111, and/or the second metal layer 115 may be substantially parallel with respect to planar surface portions of the substrate 101 and/or the insulating layer 105. Accordingly, one or more of portions of the metal layer 107a, the dielectric layer 109, the conductive layer 111, and/or the second metal layer 115 may be substantially planar. Moreover, the substrate 101 and/or the insulating layer 105 may be substantially rigid so that portions of the metal layer 107a, the dielectric layer 109, the conductive layer 111, and/or the second metal layer 115 may be maintained substantially planar.

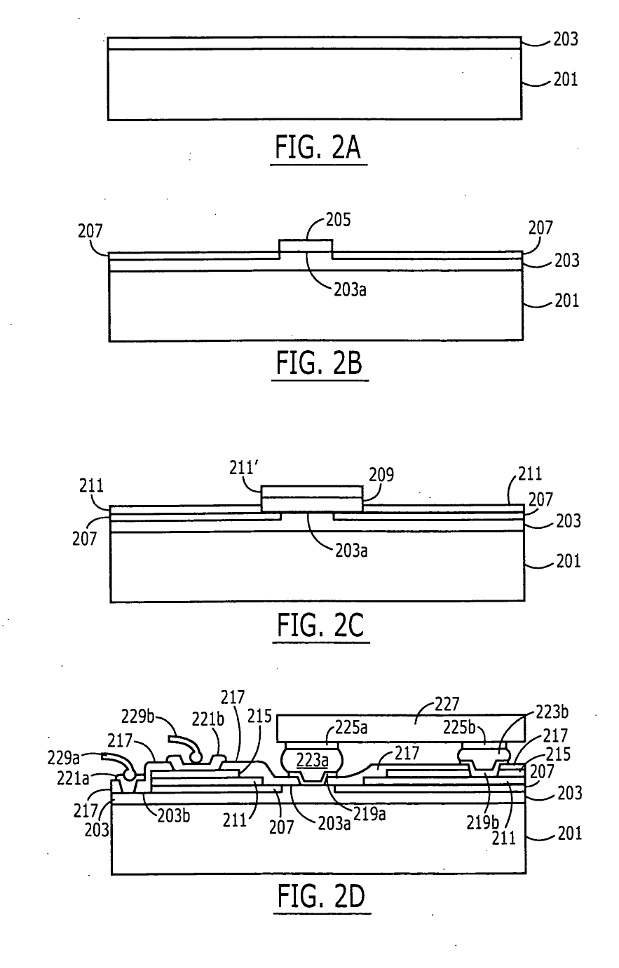

According to additional embodiments of the present invention, MIM structures may be provided on sub-mounts for discrete electronic devices (such as light emitting diodes) or integrated circuit devices. As shown in FIG. 2A, a first metal layer 203 (also referred to as a first metal electrode) may be formed on a sub-mount substrate 201, and the sub-mount substrate 201 may be formed of insulating and/or conductive material(s). The first metal electrode layer 203, for example, may be a layer of a metal such as aluminum and/or tantalum, and the first metal layer 207 may be formed using a thin film deposition technique, such as sputtering, chemical vapor deposition (CVD), atomic layer deposition (ALD), etc. In an alternative, a surface portion (or an entirety) of the sub-mount substrate 201 may be formed of a metal suitable for the first metal electrode (such as aluminum and/or tantalum) so that a separate step of forming the first metal layer is not required. Stated in other words, a surface portion of the sub-mount substrate 201 may provide the first metal layer 203.

As shown in FIG. 2B, a mask 205 (such as a photoresist mask) may be formed on a portion of the first metal layer 203, and surface portions of the first metal layer 203 not covered by the mask 205 may be converted to an oxide (such as aluminum oxide and/or tantalum oxide) to provide a dielectric layer 207. More particularly, exposed portions of the first metal layer 203 may be converted to an oxide using oxidation, anodization, and/or electrolytic reaction. After converting exposed surface portions of the first metal layer 203 to an oxide, the mask 205 may be removed so that an exposed portion 203a of the first metal layer 203 is surrounded by the dielectric oxide layer 207.

As shown in FIG. 2C, a mask 209 (such as a second photoresist mask) may be formed on the exposed portion 203a of the first metal layer 203 and on portions of the dielectric layer 207 surrounding the exposed portion 203a of the first metal layer 203. The mask 209 thus covers a larger area than the mask 205. A conductive layer 211 of a material such as manganese oxide is then formed on the mask 209 and on portions of the dielectric layer 207 exposed by the mask 209. A conductive layer of manganese oxide (MnO₂) may be formed, for example, by sputtering or by application in an aqueous solution and then drying. The mask 209 can then be removed together with portions of the conductive layer 211′ on the mask 209. Accordingly, an exposed portion of the first metal layer 203 may be exposed by the dielectric layer 207, and exposed portions of the dielectric layer 207 may be surrounded by the conductive layer 211.

As shown in FIG. 2D, a second metal layer 215 (also referred to as a second metal electrode) may be formed on the conductive layer 211, and the second metal layer 215 may be patterned (for example, using photolithographic processing techniques) to expose portions of the conductive layer 211 surrounding exposed portions of the dielectric layer 207. Accordingly, portions of the second metal layer 215 on left and right sides of FIG. 2D may be coupled through portions of the second metal layer 215 not shown in the cross-sectional view of FIG. 2D, and portions of the conductive layer 211 on left and right sides of FIG. 2D may be coupled through portions of the conductive layer 211 not shown in the cross-sectional view of FIG. 2D. In addition, portions of the second metal layer 215, the conductive layer 211, and the dielectric layer 207 may be removed to expose a portion 203b of the first metal layer 203 for subsequent coupling therewith.

As discussed above with respect to FIGS. 2A-D, separate patterning and/or masking steps may be used to pattern the dielectric layer 207, the conductive layer 211, and the second metal layer 215 to provide the stair step pattern shown in FIG. 2D. In an alternative, each of the dielectric layer, the conductive layer, and the second metal layer may be formed as continuous layers and then patterned using a single masking step. Accordingly, a structure without a stair step profile may be provided. In another alternative, the dielectric layer 207 may be formed as discussed above with respect to FIG. 2B, and the conductive layer 211 and the second metal layer 215 can be patterned using a same mask so that both the conductive layer 211 and the metal layer 215 are set back a same distance from the exposed portion 203a of the first metal layer 203. For example, a single lift off mask or a single etch mask may be used to pattern the conductive layer 211 and the second metal layer 215.

An insulting layer 217 may then be formed on the second metal layer 215, on the conductive layer 211, on the dielectric layer 207, and on the first metal layer 203. The insulating layer 217 may then be patterned to expose portions of the first and second metal layers 203 and 215 for subsequent wire and/or solder bonds. Underbump metallurgy layers 219a-b and/or wirebond pads 221a-b may be formed on exposed portions of the first and second metal layers 203 and 215. As shown in FIG. 2D, solder bumps 223a-b may provide electrical and mechanical coupling with pads 225a-b of electronic device 227 (such as a light emitting diode), and wirebonds 229a-b may provide electrical coupling with a next level of packaging such as a leadframe, an integrated circuit device, a printed circuit board, a sub-mount, an electronic module, etc.

Each of the underbump metallurgy layers 219a-b and/or wirebond pads 221a-b may be configured to provide coupling for wire and/or solder bonds. U.S. Pat. No. 6,762,122, for example, discusses a metallurgy structure suitable for both wire and solder bonding so that a same structure can be provided for both the underbump metallurgy layers 219a-b and the wirebond pads 221a-b. U.S. Pat. No. 6,762,122 is assigned to the assignee of the present invention, and the disclosure of U.S. Pat. No. 6,762,122 is hereby incorporated herein in its entirety by reference.

In the assembly illustrated in FIG. 2D, the wire 229a is electrically coupled to the solder bump 223a through the first metal layer 203, and the wire 229b is electrically coupled to the solder bump 223b through the second metal layer 215. During normal operation of the electronic device 227 at normal operating voltages, the dielectric layer 207 of the MIM structure substantially blocks direct electrical communication between the first and second metal layers 207 and 215. If an excessive voltage is generated between the first and second metal layers 207 and 215 (for example, as a result of an electrostatic discharge), electron tunneling through the dielectric layer 207 of the MIM structure may allow current flow to dissipate energy thereby protecting the electronic device 227.

Moreover, the conductive layer 211 may provide self-healing for the MIM structure in the event of breakdown of the dielectric layer 207. In particular, the conductive material comprises a conductive material (such as manganese dioxide) that decomposes into an insulating material (such as manganic oxide) once a temperature threshold is exceeded. Accordingly, a dielectric breakdown resulting from an electrostatic discharge may provide a localized increase in temperature of the conductive layer 211 in the vicinity of the dielectric breakdown above the threshold for decomposition, so that portions of the conductive layer in the vicinity of the breakdown decompose into an insulating material. A short circuit and/or excessive leakage current between the first and second metal layers 207 and 215 may thus be avoided even though dielectric breakdown of the dielectric layer 207 has occurred. Moreover, the MIM structure may provide ESD protection after one or more breakdowns of the dielectric layer because the conductive layer 211 maintains its conductivity away from the region(s) of prior dielectric breakdown(s).

As shown in FIG. 2D, electrical coupling to a next level of packaging may be provided through wires 229a-b bonded to wirebond pads 221a-b. Other couplings, however, may be provided. For example, solder bumps could be provided instead of wires. Moreover, both couplings do not need to be provided on a same side of the substrate 201. According to some embodiments, a coupling to the second metal layer 215 may be provided on a top side of the substrate 201, and a coupling to the first metal layer 203 may be provided on a bottom side of the substrate 201. By way of example, the substrate 201 or portions thereof may be conductive so that electrical coupling to the first metal layer 203 may be provided using a contact on the bottom side of the substrate 201.

According to some embodiments of the present invention, the electronic device 227 of FIG. 2D may be a light emitting diode (LED), the substrate 201 may be conductive, and the wire 229a and wirebond pad 221a may be eliminated. Moreover, the backside of the conductive substrate 201 (opposite the electronic device 227) may be mounted on an LED assembly cathode, and a second end of the wire 229b may be bonded to an LED assembly anode. The electronic device 227, the sub-mount, and portions of the cathode and anode may then be encapsulated in a translucent packaging material to provide an LED assembly. Cathodes, anodes, and translucent packaging materials for LED assemblies are discussed, for example, in U.S. Pat. Nos. 6,642,550 and 5,914,501, the disclosures of which are hereby incorporated herein in their entirety by reference.

As shown in FIG. 2D, surface portions of the substrate 201 may be planar, and portions of the metal layer 203, the dielectric layer 207, the conductive layer 211, and/or the second metal layer 215 may be substantially parallel with respect to planar surface portions of the substrate 201. Accordingly, one or more of portions of the metal layer 203, the dielectric layer 207, the conductive layer 211, and/or the second metal layer 215 may be substantially planar. Moreover, the substrate 201 may be substantially rigid so that portions of the metal layer 203, the dielectric layer 207, the conductive layer 211, and/or the second metal layer 215 may be maintained substantially planar.

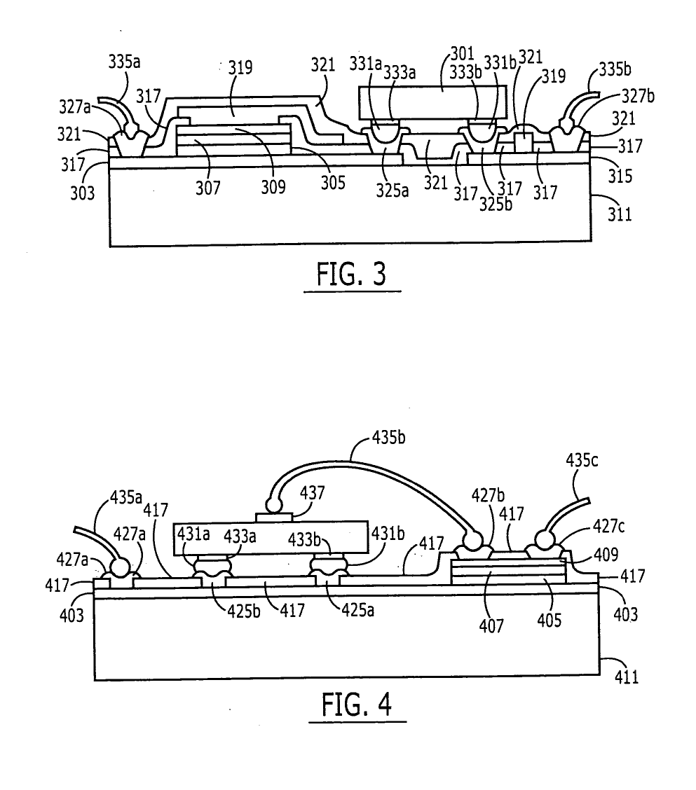

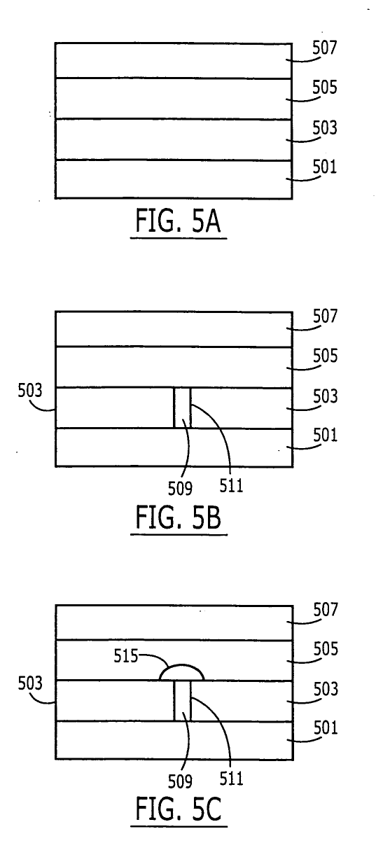

Additional sub-mount structures and assemblies according to embodiments of the present invention are illustrated in FIGS. 3 and 4. As shown in FIG. 3, a sub-mount for an electronic device 301 may include a MIM structure having a first metal layer 303 (also referred to as a first metal electrode), a dielectric layer 305, a conductive layer 307, and a second metal layer 309 (also referred to as a second metal electrode) on an insulating surface of a sub-mount substrate 311. In addition, a metal layer 315 may be patterned from a same layer of metal used to form the first metal layer 303, with the metal layers 303 and 315 being electrically isolated. An insulating layer 317 may be formed on the MIM structure, the first metal layer 303, the substrate 311, and the metal layer 315, and contact holes in the insulating layer 317 may expose portions of the second metal layer 309 and metal layer 315. A metal runner 319 on the insulating layer 317 may provide electrical coupling between the second metal layer 309 of the MIM structure and the metal layer 315. A single layer of metal may be patterned to provide a continuous runner 319 coupling the metal layers 309 and 315. Portions of the runner 319 on left and right sides of FIG. 3 may be directly coupled out of the plane shown in the cross-sectional view of FIG. 3.

A second insulating layer 321 may be provided on the first insulating layer 317 and on the runner 319, and holes though the first and second insulating layers 317 and 321 may expose portions of the metal layers 303 and 315 for coupling with solder bumps and/or wirebonds. Underbump metallurgy layers 325a-b and wirebond pads 327a-b may be provided in/on respective contact holes. Under bump metallurgy layers and/or wirebond pads may be provided as discussed above with regard to FIGS. 2A-D. Solder bumps 331a-b may provide electrical and mechanical coupling between the sub-mount and pads 333a-b of electronic device 301 (such as a light emitting diode), and wires 335a-b may provide electrical coupling to a next layer of packaging such as a printed circuit board, a sub-mount, a leadframe, an electronic module, an integrated circuit device, etc. While wires 335a-b are shown providing electrical coupling with a next level of packaging, electrical coupling may be provided by other couplings such as solder bumps.

As discussed above with regard to FIGS. 2A-D, the first metal layer 303 may comprise a layer of metal such as aluminum and/or tantalum, and the dielectric layer 305 may be an oxide of the metal of the first metal layer 303. More particularly, the dielectric layer 305 may be formed by converting a portion of the first metal layer 303 to an oxide, for example, using oxidation, anodization, and/or electrolytic reaction. The conductive layer 307 may be a layer of a conductive metal oxide (such as manganese dioxide) that decomposes into an insulating oxide (such as manganic oxide) once a threshold temperature is exceeded. The second metal layer 309 may be a layer of a metal such as aluminum and/or tantalum. According to some embodiments of the present invention, portions of the runner 319 may function as the second metal electrode so that a separate layer 309 is not required.

During normal operation of the electronic device 301 at normal operating voltages, the dielectric layer 305 of the MIM structure substantially blocks direct electrical communication between the first and second metal layers 303 and 309. If an excessive voltage is generated between the first and second metal layers 303 and 309 (for example, as a result of an electrostatic discharge), electron tunneling through the dielectric layer 305 of the MIM structure may allow current flow to dissipate energy of the electrostatic discharge thereby protecting the electronic device 301.

Moreover, the conductive layer 307 may provide self-healing for the MIM structure in the event of breakdown of the dielectric layer 305. In particular, the conductive layer 307 may comprise a conductive material (such as manganese dioxide) that decomposes into an insulating material (such as manganic oxide) once a temperature threshold is exceeded. Accordingly, a dielectric breakdown resulting from an electrostatic discharge may provide a localized increase in temperature of the conductive layer 307 in the vicinity of the dielectric breakdown above the threshold for decomposition, so that portions of the conductive layer in the vicinity of the breakdown decompose into an insulating material. A short circuit and/or excessive leakage current between the first and second metal layers 303 and 309 may thus be avoided even though dielectric breakdown of the dielectric layer 305 has occurred. Moreover, the MIM structure may provide ESD protection after one or more breakdowns of the dielectric layer because the conductive layer 307 maintains its conductivity away from the region(s) of prior dielectric breakdown(s).

Moreover, a second MIM structure may be provided on the sub-mount of FIG. 3. For example, a second MIM structure may be provided between the runner 319 and the metal layer 315 so that first and second MIM structures according to embodiments of the present invention are coupled in series. Accordingly, energy of an electrostatic discharge may be dissipated in series through the first and second MIM structures. The first and second MIM structures may be formed using the same layers and patterning steps. According to other embodiments of the present invention, first and second MIM structures may be cross-coupled in parallel. More particularly, respective runners may electrically couple the top electrode of each MIM structure with the bottom electrode of the other MIM structure. Accordingly, energy from an electrostatic discharge may be primarily dissipated through one or the other of the MIM structures depending on the polarity of the discharge.

According to some embodiments of the present invention, the electronic device 301 of FIG. 3 may be a light emitting diode. Moreover, a second end of the wire 335a may be bonded to an LED assembly cathode, and a second end of the wire 335b may be bonded to an LED assembly anode. The electronic device 301, the sub-mount, and portions of the cathode and anode may then be encapsulated in a translucent packaging material to provide an LED assembly. Cathodes, anodes, and translucent packaging materials for LED assemblies are discussed, for example, in U.S. Pat. Nos. 6,642,550 and 5,914,501, the disclosures of which are hereby incorporated herein in their entirety by reference.

As shown in FIG. 4, a sub-mount for an electronic device 401 may include a MIM structure having a first metal 403 (also referred to as a first metal electrode), a dielectric layer 405, a conductive layer 407, and a second metal 409 (also referred to as a second metal electrode) on a surface of a sub-mount substrate 411. If a surface portion and/or an entirety of the substrate 411 comprises an appropriate metal (such as aluminum and/or tantalum), a separate layer for the metal layer 403 may not be required. An insulating layer 417 may be formed on the MIM structure and the first metal layer 403, and contact holes in the insulating layer 417 may expose portions of the first and second electrodes 403 and 409 for coupling with solder bumps and/or wirebonds.

Underbump metallurgy layers 425a-b and wirebond pads 427a-c may be provided in respective contact holes. Under bump metallurgy layers and/or wirebond pads may be provided as discussed above with regard to FIGS. 2A-D. Solder bumps 431a-b may provide electrical and mechanical coupling between the sub-mount and pads 433a-b of electronic device 401 (such as a light emitting diode), and wires 435a and 435c may provide electrical coupling to a next layer of packaging such as a printed circuit board, a sub-mount, a leadframe, an electronic module, an integrated circuit device, etc. While wires 435a and 435c are shown providing electrical coupling with a next level of packaging, electrical coupling may be provided by other couplings such as solder bumps. Moreover, wire 435b may provide electrical coupling between pad 437 of the electronic device 401 and the second metal layer 409 of the MIM structure. In FIG. 4, the electronic device 401 may be a “vertical” device meaning that current flows between opposing surfaces of the substrate. The two solder bumps 431a-b may be electrically redundant with the second bump providing mechanical stability and/or one of the pads 433a or 433b may be electrically non-functional.

As discussed above with regard to FIGS. 2A-D, the first metal electrode 403 may comprise a layer of metal such as aluminum and/or tantalum, and the dielectric layer 405 may be an oxide of the metal of the first electrode 403. More particularly, the dielectric layer 405 may be formed by converting a portion of the first metal electrode 403 to an oxide, for example, using oxidation, anodization, and/or electrolytic reaction. The conductive layer 407 may be a layer of a conductive metal oxide (such as manganese dioxide) that decomposes into an insulating oxide (such as manganic oxide) once a threshold temperature is exceeded. The second metal electrode 409 may be a layer of a metal such as aluminum and/or tantalum.

During normal operation of the electronic device 401 at normal operating voltages, the dielectric layer 405 of the MIM structure substantially blocks direct electrical communication between the first and second metal electrodes 403 and 409. If an excessive voltage is generated between the first and second metal electrodes 403 and 409 (for example, as a result of an electrostatic discharge), electron tunneling through the dielectric layer 405 of the MIM structure may allow current flow to dissipate energy thereby protecting the electronic device 401.

Moreover, the conductive layer 407 may provide self-healing for the MIM structure in the event of breakdown of the dielectric layer 405. In particular, the conductive material may comprise a conductive material (such as manganese dioxide) that decomposes into an insulating material (such as manganic oxide) once a temperature threshold is exceeded. Accordingly, a dielectric breakdown resulting from an electrostatic discharge may provide a localized increase in temperature of the conductive layer 407 in the vicinity of the dielectric breakdown above the threshold for decomposition, so that portions of the conductive layer in the vicinity of the breakdown decompose into an insulating material. A short circuit and/or excessive leakage current between the first and second metal electrodes 403 and 409 may thus be avoided even though dielectric breakdown of the dielectric layer 405 has occurred. Moreover, the MIM structure may provide ESD protection after one or more breakdowns of the dielectric layer because the conductive layer 407 maintains its conductivity away from the region(s) of prior dielectric breakdown(s).

Moreover, a second MIM structure may be provided on the sub-mount of FIG. 4. For example, a second MIM structure may be provided in series with the first MIM structure. In an alternative, a second MIM structure may be cross-coupled in parallel with the first MIM structure.

According to some embodiments of the present invention, the electronic device 401 of FIG. 4 may be a light emitting diode (LED), the substrate 411 may be conductive, and the wire 435a and wirebond pad 427a may be eliminated. Moreover, the backside of the conductive substrate 411 (opposite the electronic device 401) may be mounted on an LED assembly cathode, and a second end of the wire 435c may be bonded to an LED assembly anode. The electronic device 401, the sub-mount, and portions of the cathode and anode may then be encapsulated in a translucent packaging material to provide an LED assembly. Cathodes, anodes, and translucent packaging materials for LED assemblies are discussed, for example, in U.S. Pat. Nos. 6,642,550 and 5,914,501, the disclosures of which are hereby incorporated herein in their entirety by reference.

As discussed above with respect to each of FIGS. 1A-C, 2A-D, and 3-4, MIM structures according to embodiments of the present invention may be used to provide ESD protection for discrete and/or integrated circuit electronic devices. More particularly, a first conductive electrode 501 (such as a layer of aluminum and/or tantalum), a dielectric layer 503 (such as a layer of aluminum oxide and/or tantalum oxide), a conductive layer 505 of a conductive material (such as manganese oxide) that decomposes into a non-conductive material (such as manganic oxide), and a second conductive electrode 507 (such as a layer of aluminum and/or tantalum) may be provided as shown in FIG. 5A. The structure of FIG. 5A can be provided as discussed above with respect to any of FIGS. 1A-C, 2A-D, and 3-4.

At normal operating voltages of an electronic device coupled to the MIM structure of FIG. 5A, the dielectric layer 503 substantially blocks electrical current flow between the first and second conductive electrodes 501 and 507. During an electrostatic discharge, electron tunneling through the dielectric layer 503 may dissipate energy of the electrostatic discharge thereby protecting the electronic device coupled to the MIM structure. During an electrostatic discharge, however, breakdown of the dielectric layer 503 may occur at a breakdown location 511, and metal 509 from the first conductive electrode may migrate into the breakdown location 511 of the dielectric layer 503 so that a conductive path through the dielectric layer 503 may result as shown in FIG. 5B.

Localized heat may be generated as a result of the dielectric breakdown and/or concentrated current flow at the breakdown location 511, and this localized heat may exceed a temperature threshold for decomposition of a portion of the conductive layer 505. Accordingly, a portion of the conductive layer 505 may decompose into the non-conductive material 515 while other portions of the conductive layer 505 are maintained as the conductive material. Accordingly, a short-circuit resulting from dielectric breakdown may be cured, and sufficient undamaged portions of the dielectric layer 503 and the conductive layer 505 may continue to provide ESD protection after one or more dielectric breakdowns. The electrostatic discharge and self-healing operations illustrated in FIGS. 5A-C may be provided by any of the structures illustrated in FIGS. 1C, 2D, 3, and/or 4.

While the present invention has been particularly shown and described with reference to embodiments thereof, it will be understood by those skilled in the art that various changes in form and details may be made therein without departing from the spirit and scope of the invention as defined by the appended claims and their equivalents.

1. A method of forming a metal-insulator-metal structure, the method comprising:
providing a first conductive electrode on a substrate;
forming a dielectric layer on the first conductive electrode;
forming a second conductive electrode on the dielectric layer so that the dielectric layer is between the first and second conductive electrodes; and
forming a conductive layer between the dielectric layer and one of the first and second conductive electrodes wherein the conductive layer comprises a conductive material that decomposes into a non-conductive material once a threshold temperature has been exceeded.

2. A method according to claim 1 wherein forming the conductive layer comprises forming the conductive layer after forming the dielectric layer and before forming the second conductive electrode.

3. A method according to claim 1 wherein the first conductive electrode comprises a metal layer and wherein forming the dielectric layer comprises converting a surface portion of the metal layer into an oxide.

4. A method according to claim 3 wherein the metal layer comprises at least one of aluminum and/or tantalum and wherein the dielectric layer comprises at least one of aluminum oxide and/or tantalum oxide.

5. A method according to claim 1 wherein forming the second conductive layer comprises forming the second conductive using thin film deposition on the conductive layer.

6. A method according to claim 1 wherein the conductive material comprises a conductive metal oxide that decomposes into a non-conductive metal oxide once the threshold temperature has been exceeded.

7. A method according to claim 1 wherein the conductive layer comprises manganese dioxide (MnO₂).

8. A method according to claim 7 wherein the conductive manganese dioxide (MnO₂) decomposes into insulating manganic oxide (Mn₂O₃) once the threshold temperature has been exceeded.

9. A method according to claim 1 wherein the dielectric layer comprises an insulating metal oxide.

10. A method according to claim 1 wherein each of the first and second conductive electrodes comprises a metal.

11. A method according to claim 10 wherein the metal comprises at least one of aluminum and/or tantalum.

12. A method according to claim 1 wherein the substrate comprises an integrated circuit substrate including an input/output pad and wherein one of the first or second conductive electrodes is coupled to the input/output pad.

13. A method according to claim 12 wherein one of the first or second conductive electrodes is directly coupled to the input/output pad through a conductive runner on the substrate.

14. A method according to claim 12 further comprising:
coupling the input/output pad to a second substrate other than the integrated circuit substrate.

15. A method according to claim 1 further comprising:
coupling the first electrode to a first terminal of an electronic device; and
coupling the second electrode to a second terminal of the electronic device.

16. A method according to claim 15 wherein the electronic device comprises a light emitting diode.

17. A method according to claim 15 the first electrode is coupled to the first terminal using at least one of a solder bond and/or a wirebond.

18. A method according to claim 15 further comprising:
coupling at least one of the first electrode and/or the second electrode to a second substrate other the first substrate and other than a substrate of the electronic device.

19. A method according to claim 1 wherein the substrate is rigid and wherein at least a portion of each of the dielectric layer, the second conductive electrode, and the conductive layer is parallel with respect to a surface of the substrate.

20. A method according to claim 1 wherein the first conductive electrode comprises tantalum and the second conductive electrode comprises a tantalum sub-layer and an aluminum sub-layer such that the tantalum sub-layer is between the aluminum sub-layer and the first conductive electrode.

21. A method according to claim 1 wherein providing the first conductive electrode comprises forming the first conductive electrode using thin film deposition on the substrate.

22. A method according to claim 1 further comprising:
after forming the second conductive electrode, decomposing a portion of the conductive layer into the non-conductive material while maintaining other portions of the conductive layer as the conductive material.

23. A metal-insulator-metal structure comprising:
a substrate;
a first conductive electrode on the substrate;
a dielectric layer on the first conductive electrode;
a second conductive electrode on the dielectric layer so that the dielectric layer is between the first and second conductive electrodes; and
a conductive layer between the dielectric layer and one of the first and second conductive electrodes wherein the conductive layer comprises a conductive material that decomposes into a non-conductive material once a threshold temperature has been exceeded.

24-40. (canceled)
